(19) United States
(12) Patent Application Publication
(10) Pub. No.: US 2026/0004718 A1
(43) Pub. Date: Jan. 1, 2026

(54) DISPLAY PANEL AND ELECTRONIC DEVICE INCLUDING THE SAME

(71) Applicant: Samsung Display Co., Ltd., Yongin-si (KR)

(72) Inventors: DOYEONG PARK, Yongin-si (KR); YUNMI KIM, Yongin-si (KR); HYEONGSEOK KIM, Yongin-si (KR); DONG HEE SHIN, Yongin-si (KR)

(21) Appl. No.: 19/182,316

(22) Filed: Apr. 17, 2025

(30) Foreign Application Priority Data
Jul. 1, 2024 (KR) 10-2024-0086268

(51) Int. Cl. G09G 3/32

(52) U.S. Cl. CPC G09G 3/32; G09G 2310/0267; G09G 2310/08

(57) ABSTRACT

A display panel includes: a plurality of pixels; a plurality of scan lines electrically connected to the plurality of pixels; a plurality of stages electrically connected to the plurality of scan lines and arranged along a first direction; and a plurality of carry lines connected to the plurality of stages, wherein: the plurality of stages include a first stage, a second stage, and a third stage; the plurality of carry lines include a first carry line connected to the first stage and the second stage, a second carry line connected to the first stage, the second stage, and the third stage, and a third carry line connected to the second stage and the third stage; and in a region in which the second stage is located, the first carry line and the third carry line do not overlap each other in a second direction intersecting the first direction.

### CROSS-REFERENCE TO RELATED APPLICATION

The present application claims priority to and the benefit of Korean Patent Application No. 10-2024-0086268, filed on Jul. 1, 2024, the entire content of which is incorporated herein by reference.

### BACKGROUND

Aspects of some embodiments of the present disclosure herein relate to a display panel and an electronic device.

Multimedia electronic devices such as televisions, mobile phones, tablets, computers, navigation system units, and game consoles include a display panel for displaying images. According to the demand of the market, research has been conducted to reduce a region (non-display region or bezel region) in the display panel, the region in which an image is not displayed.

The above information disclosed in this Background section is only for enhancement of understanding of the background and therefore the information discussed in this Background section does not necessarily constitute prior art.

### SUMMARY

Aspects of some embodiments of the present disclosure herein relate to a display panel and an electronic device, and for example, to a display panel having a non-display region with a relatively reduced width and an electronic device including the same.

Aspects of some embodiments of the present disclosure include a display device having a non-display region with a relatively reduced width and an electronic device including the same.

Aspects of some embodiments of the present disclosure include a display panel including a plurality of pixels, a plurality of scan lines electrically connected to the plurality of pixels, a plurality of stages electrically connected to the plurality of scan lines and arranged along a first direction, and a plurality of carry lines connected to the plurality of stages, wherein the plurality of stages include a first stage, a second stage, and a third stage, wherein the plurality of carry lines include a first carry line connected to the first stage and the second stage, a second carry line connected to the first stage, the second stage, and the third stage, and a third carry line connected to the second stage and the third stage, and in a region in which the second stage is located, the first carry line and the third carry line do not overlap each other in a second direction intersecting the first direction.

According to some embodiments, the second carry line may include a curved portion, wherein the curved portion may overlap a region between an end of the first carry line and an end of the third carry line.

According to some embodiments, the first stage may be an X−1-th stage, the second stage may be an X-th stage, and the third stage may be an X+1-th stage, wherein the X may be an integer of 2 or greater.

According to some embodiments, the first stage may be an X−2-th stage, the second stage may be an X-th stage, and the third stage may be an X+2-th stage, wherein the X may be an integer of 3 or greater.

According to some embodiments, the second carry line may include a first line portion, a second line portion electrically connected to the first line portion, and a connection portion connected to the first line portion and the second line portion, wherein the first line portion and the second line portion may be on the same layer, and the connection portion may be on a different layer from the first line portion and the second line portion.

According to some embodiments, the first carry line and the first line portion may be spaced apart in a second direction intersecting the first direction, and the second line portion and the third carry line may be spaced apart in the second direction.

According to some embodiments, the first carry line may be spaced apart from the second line portion in the first direction, and the first line portion and the third carry line may be spaced apart in the first direction.

According to some embodiments, the second stage may be electrically connected to six scan lines among the plurality of scan lines.

According to some embodiments, each of the plurality of stages may include a plurality of clock terminals configured to receive a plurality of clock signals, wherein in a first mode driven at a first frequency, the plurality of clock signals may have different phases from each other, and in a second mode driven at a second frequency higher than the first frequency, some clock signals among the plurality of clock signals may have the same phase.

According to some embodiments, the plurality of pixels may include Y pixels (Y is an integer of 2 or greater) arranged along the first direction, wherein the second stage may output scan signals to Y scan lines connected to the Y pixels among the plurality of scan lines.

According to some embodiments, in a first mode driven at a first frequency, first-mode scan signals output to the Y scan lines may have different phases from each other, and in a second mode driven at a second frequency higher than the first frequency, some second-mode scan signals among second-mode scan signals output to the Y scan lines may have the same phase as each other.

According to some embodiments, the plurality of scan lines may include a plurality of first scan lines and a plurality of second scan lines, wherein the plurality of stages may include a plurality of first-type stages electrically connected to the plurality of first scan lines and a plurality of second-type stages electrically connected to the plurality of second scan lines, wherein the plurality of first-type stages and the plurality of second-type stages may be alternately and repeatedly arranged one by one along the first direction.

According to some embodiments, each of the plurality of pixels may include a light emitting element, a first transistor, a second transistor, and a third transistor, wherein the first transistor may be connected to the light emitting element, the second transistor may be connected to a gate electrode of the first transistor, and the third transistor may be connected to the light emitting element, wherein the operation of the second transistor may be controlled by one corresponding first scan line among the plurality of first scan lines, and the operation of the third transistor may be controlled by one corresponding second scan line among the plurality of second scan lines.

According to some embodiments of the present disclosure, a display panel includes a plurality of pixels arranged along a first direction, a plurality of scan lines connected to the plurality of pixels, a reference stage configured to output a plurality of scan signals to the plurality of scan lines, a first peripheral stage spaced apart from the reference stage in the first direction, a second peripheral stage spaced apart from the first peripheral stage in the first direction with the reference stage interposed therebetween, a first peripheral carry line configured to transfer a carry signal output from the first peripheral stage, and a second peripheral carry line configured to transfer a carry signal output from the second peripheral stage, wherein the first peripheral carry line and the second peripheral carry line do not overlap each other in a second direction intersecting the first direction.

According to some embodiments, in a first mode driven at a first frequency, the plurality of scan signals may have different phases from each other, and in a second mode driven at a second frequency higher than the first frequency, some scan signals among the plurality of scan signals may have the same phase as each other.

According to some embodiments, the display panel may further include a carry line configured to output a carry signal generated from the reference stage, wherein the carry line may include a curved portion, wherein the curved portion may overlap a region between an end of the first peripheral carry line and an end of the second peripheral carry line.

According to some embodiments, the carry line may further include a first line portion, a second line portion electrically connected to the first line portion, and a connection portion connected to the first line portion and the second line portion, wherein the first line portion and the second line portion may be on the same layer, and the connection portion may be on a different layer from the first line portion and the second line portion.

According to some embodiments, the first peripheral carry line and the first line portion may be spaced apart in the second direction intersecting the first direction, and the second line portion and the second peripheral carry line may be spaced apart in the second direction.

According to some embodiments, the first peripheral carry line may be spaced apart from the second line portion in the first direction, and the first line portion and the second peripheral carry line may be spaced apart in the first direction.

According to some embodiments of the present disclosure, an electronic device includes a plurality of pixels arranged along a first direction, a stage including a plurality of clock terminals configured to control the operation of the plurality of pixels and receiving a plurality of clock signals, a first carry line configured to transfer a first carry signal to the stage, a second carry line configured to transfer a second carry signal generated from the stage, and a third carry line configured to transfer a third carry signal to the stage, wherein when viewed in a second direction intersecting the first direction, the first carry line and the third carry line are spaced apart from each other, in a first mode driven at a first frequency, the plurality of clock signals have different phases from each other, and in a second mode driven at a second frequency higher than the first frequency, some clock signals among the plurality of clock signals have the same phase.

### BRIEF DESCRIPTION OF THE FIGURES

The accompanying drawings are included to provide a further understanding of aspects of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a perspective view of an electronic device according to some embodiments of the present disclosure;

FIG. 2 is a plan view of an electronic device according to some embodiments of the present disclosure;

FIG. 3 is a block diagram of an electronic device according to some embodiments of the present disclosure;

FIG. 4 is an equivalent circuit diagram of a pixel according to some embodiments of the present disclosure;

FIG. 5 is a block diagram illustrating some components of an electronic device according to some embodiments of the present disclosure;

FIG. 6A is a view illustrating a scan driving circuit according to some embodiments of the present disclosure;

FIG. 6B is an equivalent circuit diagram illustrating one stage according to some embodiments of the present disclosure;

FIG. 7 is a timing diagram for describing an operation of a stage in a first mode according to some embodiments of the present disclosure;

FIG. 8 is a timing diagram of a plurality of clock signals for describing an operation of a stage in a second mode according to some embodiments of the present disclosure;

FIG. 9 is a view illustrating an activation state of a first scan signal and a second scan signal and changes in luminance according to some embodiments of the present disclosure;

FIG. 10 is a view illustrating an activation state of a first scan signal and a second scan signal and changes in luminance according to some embodiments of the present disclosure;

FIG. 11 is a view illustrating one group stage region according to some embodiments of the present disclosure;

FIG. 12 is a plan view illustrating a plurality of carry lines located in a line region illustrated in FIG. 11;

FIG. 13A is a plan view illustrating a plurality of carry lines according to some embodiments of the present disclosure;

FIG. 13B is a cross-sectional view taken along the line I-I′ illustrated in FIG. 13A;

FIG. 14 is a plan view illustrating a plurality of carry lines according to some embodiments of the present disclosure; and

FIG. 15 is a plan view illustrating a plurality of carry lines according to some embodiments of the present disclosure.

### DETAILED DESCRIPTION

In the present disclosure, when an element (or a region, a layer, a portion, and the like) is referred to as being “on,” “connected to,” or “coupled to” another element, it means that the element may be directly located on/connected to/coupled to the other element, or that a third element may be located therebetween.

Like reference numerals refer to like elements. Also, in the drawings, the thickness, the ratio, and the dimensions of elements are exaggerated for an effective description of technical contents. The term “and/or,” includes all combinations of one or more of which associated components may define.

The terms “first,” “second,” and the like may be used for describing various elements, but the elements should not be construed as being limited by the terms. The terms are used only for the purpose of distinguishing one component from the other. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of the components shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

The term “part” or “unit” refers to a software component or a hardware component that performs a particular function. The hardware component may include, for example, a field-programmable gate array (FPGA) or an application-specific integrated circuit (ASIC). The software component may refer to an executable code and/or data used by an executable code in an addressable storage medium. Therefore, software components may be, for example, object-oriented software components, class components, and work components, and may include processes, functions, attributes, procedures, subroutines, program code segments, drivers, firmware, micro codes, circuits, data, databases, data structures, tables, arrangements, or variables.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Hereinafter, aspects of some embodiments of the present disclosure will be described in more detail with reference to the accompanying drawings.

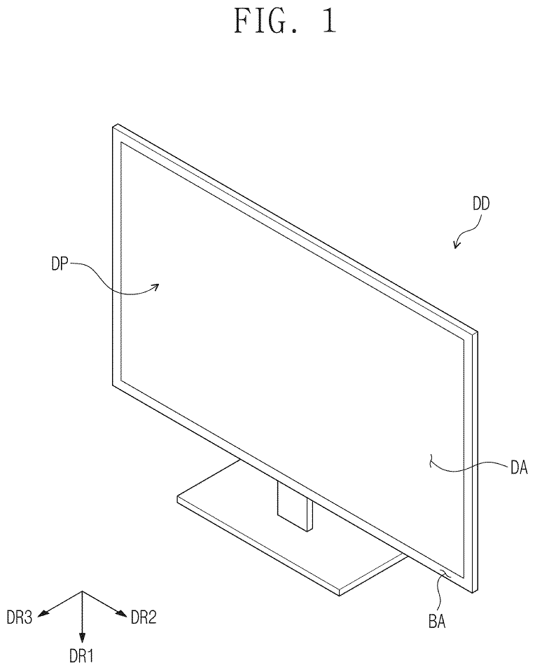

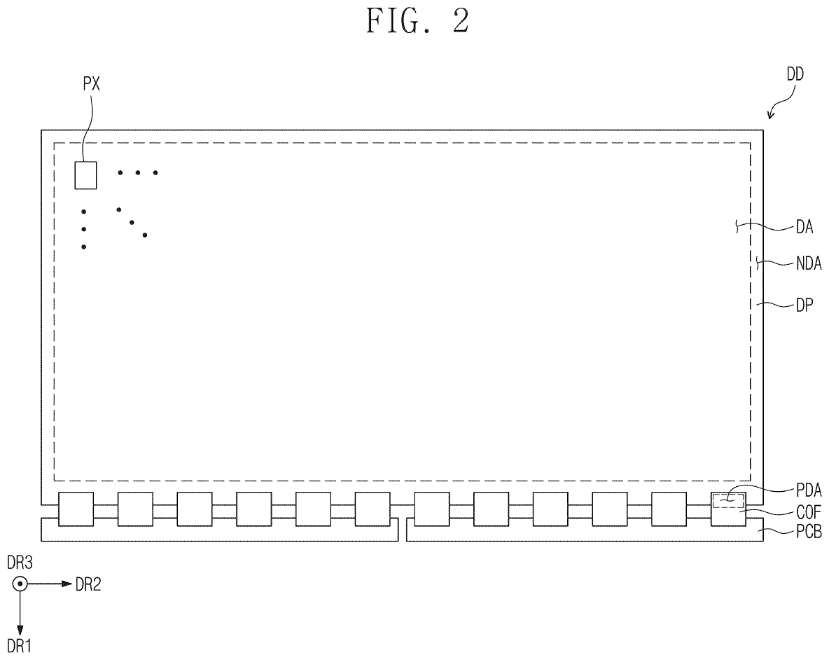

FIG. 1 is a perspective view of an electronic device DD according to some embodiments of the present disclosure. FIG. 2 is a plan view of the electronic device DD according to some embodiments of the present disclosure.

Referring to FIG. 1 and FIG. 2, the electronic device DD may be a device activated by an electrical signal. The electronic device DD may be used in large electronic devices such as televisions, monitors, or external advertisement boards, and also in small and medium-sized electronic devices such as personal computers, notebook computers, personal digital terminals, car navigation system units, game machines, portable electronic apparatuses, and cameras. It should be understood that these are merely examples, and the electronic device DD may be employed in other electronic devices without departing from the spirit and scope of embodiments according to the present disclosure. The electronic device DD illustrated in FIG. 1 may be a monitor.

The electronic device DD may include a display panel DP, a connection film COF, and a circuit board PCB.

The display panel DP may be a component which substantially generates an image. The display panel DP may be a light emitting-type display panel, and for example, the display panel DP may be an organic light emitting display panel, an inorganic light emitting display panel, an organic-inorganic light emitting display panel, a quantum-dot display panel, a micro-LED display panel, or a nano-LED display panel, but the embodiments of the present disclosure are not limited thereto. The display panel DP may have a small-and-medium size of several inches to a dozen inches or less. Alternatively, the display panel DP may have a large size of several tens of inches or more.

In the display panel DP, a display region DA and a non-display region NDA may be defined. The display panel DP may display images through the display region DA. For example, the display panel DP may include a plurality of pixels PX, and the pixels PX may be located in the display region DA. The display region DA may include a surface defined by a first direction DR1 and a second direction DR2. The display region DA may display images in a third direction DR3 intersecting the first direction DR1 and the second direction DR2. The non-display region NDA may surround the periphery of the display region DA. That is, the non-display region NDA may be outside a footprint of the display region DA.

A bezel region BA of the electronic device DD may cover at least a portion of the non-display region NDA of the display panel DP. The bezel region BA may cover the entire non-display region NDA, or may cover a portion of the non-display region NDA. If the area of the non-display region NDA is reduced, the area of the bezel region BA may also be relatively reduced.

The connection film COF may be provided in plurality. A driving circuit for driving the display panel DP, for example, a data driving circuit, may be mounted on each of the connection films COF. The plurality of connection films COF may be coupled to the non-display region NDA of the display panel DP. For example, the connection films COF may be attached to one side of the display panel DP. According to some embodiments of the present disclosure, the connection films COF may be coupled to a pad region PDA of the display panel DP. The pad region PDA may be defined in the non-display region NDA of the display panel DP. The connection films COF and the display panel DP may be coupled by an anisotropic conductive film ACF, but the embodiments of the present disclosure are not limited thereto.

A circuit board PCB may be provided in plurality. The circuit boards PCB may be electrically connected to the display panel DP through some corresponding connection films COF, respectively. A chip for controlling the operation of the display panel DP, for example, a timing controller, may be mounted on the circuit board PCB.

Although FIG. 2 illustrates six connection films COF, the embodiments of the present disclosure are not limited thereto. Although FIG. 2 illustrates two circuit boards PCB, the embodiments of the present disclosure are not limited thereto. For example, the number of connection films COF and the number of circuit boards PCB may vary depending on the resolution of the display panel DP, the size of the display panel DP, and the specification of the data driving circuit.

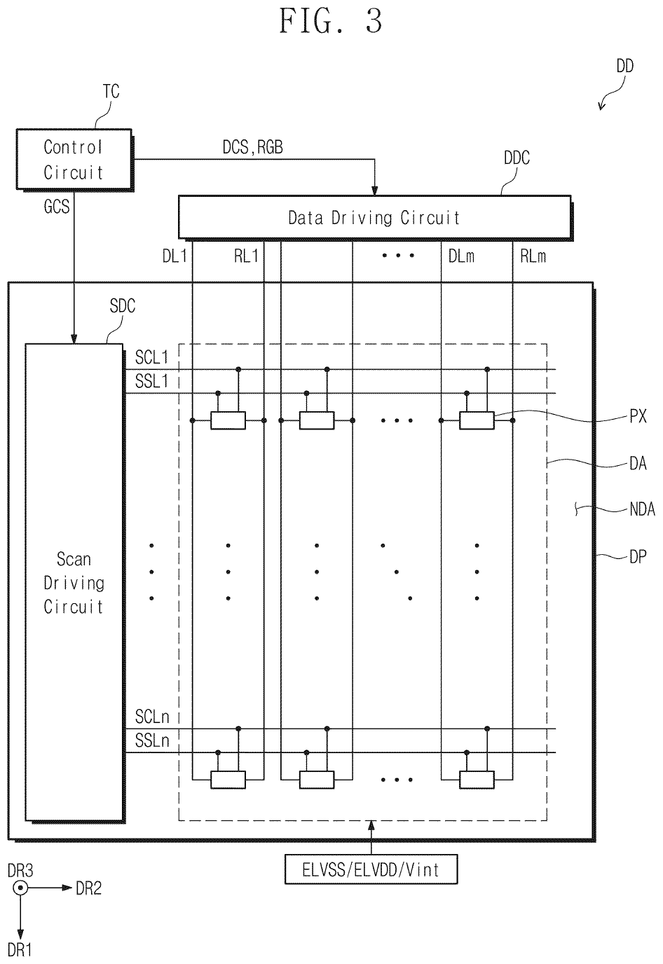

FIG. 3 is a block diagram of the electronic device DD according to some embodiments of the present disclosure.

Referring to FIG. 2 and FIG. 3, the electronic device DD may include the display panel DP, a scan driving circuit SDC, a data driving circuit DDC, and a control circuit TC.

The display panel DP includes the display region DA in which an image is displayed and the non-display region NDA located on the outside of the display region DA. In the display region DA, the plurality of pixels PX may be located. In the non-display region NDA, the scan driving circuit SDC for driving the pixels PX may be located.

The scan driving circuit SDC may be directly formed on a base layer through a photolithography process. For example, through a process of forming a pixel circuit of the pixels PX, the scan driving circuit SDC may be formed simultaneously with the pixel circuit.

The control circuit TC controls the driving of the scan driving circuit SDC and the data driving circuit DDC. The control circuit TC converts the data format of input image signals to match interface specifications with the data driving circuit DDC, thereby generating image data RGB. The control circuit TC outputs the image data RGB and various control signals DCS and GCS.

The scan driving circuit SDC receives a first control signal GCS from the control circuit TC. The first control signal GCS may include a vertical start signal which starts the operation of the scan driving circuit SDC, a clock signal which determines the output timing of signals, and the like. The scan driving circuit SDC may output a plurality of scan signals to a plurality of scan lines SCL1 to SCLn and SSL1 to SSLn. n may be an integer of 2 or greater. The scan driving circuit SDC may be referred to as a gate driving circuit.

The data driving circuit DDC receives a second control signal DCS and the image data RGB from the control circuit TC. The data driving circuit DDC converts the image data RGB into data signals, and outputs the data signals to a plurality of data lines DL1 to DLm. m may be an integer of 2 or greater. The data signals are analog voltages corresponding to gray scale values of the image data RGB. The data driving circuit DDC may be provided in the form of a driving chip and mounted on the connection films COF illustrated in FIG. 2, may be mounted on the circuit boards PCB, or may be mounted in the non-display region NDA of the display panel DP.

The display panel DP may include the plurality of scan lines SCL1 to SCLn and SSL1 to SSLn, the plurality of data lines DL1 to DLm, a plurality of lead-out lines RL1 to RLm, and the plurality of pixels PX.

The scan lines SCL1 to SCLn and SSL1 to SSLn are arranged along the first direction DR1, and each of the scan lines SCL1 to SCLn and SSL1 to SSLn may extend in the second direction DR2 intersecting the first direction DR1. The scan lines SCL1 to SCLn and SSL1 to SSLn may include first scan lines SCL1 to SCLn and second scan lines SSL1 to SSLn. The first scan lines SCL1 to SCLn may be referred to as first-type scan lines, write scan lines, or first gate lines, and the second scan lines SSL1 to SSLn may be referred to as second-type scan lines, initialization scan lines, sensing scan lines, or second gate lines.

The data lines DL1 to DLm are arranged along the second direction DR2, and each of the data lines DL1 to DLm may extend in the first direction DR1. The lead-out lines RL1 to RLm are arranged along the second direction DR2, and each of the lead-out lines RL1 to RLm may extend in the first direction DR1. The data lines DL1 to DLm and the lead-out lines RL1 to RLm may intersect the scan lines SCL1 to SCLn and SSL1 to SSLn while being insulated therefrom.

Each of the pixels PX may be connected to corresponding scan lines among the scan lines SCL1 to SCLn and SSL1 to SSLn, corresponding data lines among the data lines DL1 to DLm, and corresponding lead-out lines among the lead-out lines RL1 to RLm. For example, pixels PX arranged in a first row may be connected to a first scan line SCL1 and a first second scan line SSL1, and pixels PX arranged in an n-th row may be connected to an n-th first scan line SCLn and an n-th second scan line SSLn. Pixels PX arranged in a first column may be connected to a first data line DL1 and a first lead-out line RL1, and pixels PX arranged in an m-th column may be connected to an m-th data line DLm and an m-th lead-out line RLm. However, this is merely an example, and the connection relationship between the pixels PX and the scan lines SCL1 to SCLn and SSL1 to SSLn, the data lines DL1 to DLm, and the lead-out lines RL1 to RLm is not limited thereto.

The display panel DP receives a first power voltage ELVDD and a second power voltage ELVSS. The first power voltage ELVDD may be provided to the pixels PX. The display panel DP may receive an initialization voltage Vint. The initialization voltage Vint may be provided to the pixels PX.

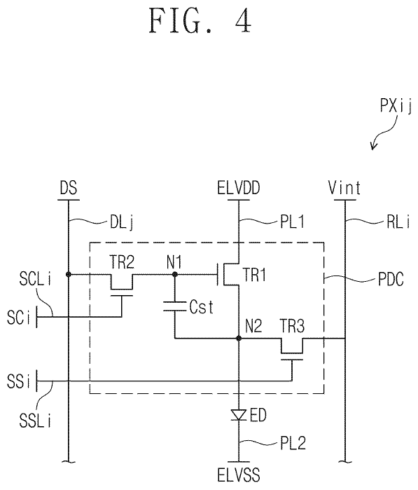

FIG. 4 is an equivalent circuit diagram of a pixel PXij according to some embodiments of the present disclosure. Although FIG. 4 illustrates various components in a pixel according to some embodiments, embodiments according to the present disclosure are not limited thereto, and according to various embodiments, the pixel may include additional components or fewer components without departing from the spirit and scope of embodiments according to the present disclosure.

FIG. 4 illustrates an example equivalent circuit diagram of one pixel PXij among the plurality of pixels PX (see FIG. 3). Because each of the plurality of pixels PX has the same circuit structure, with the provision of the description of the circuit structure for the pixel PXij, a detailed description of the rest of the pixels PX will be omitted. i may be an integer of 1 to n, and j may be an integer of 1 to m.

Referring to FIG. 4, the pixel PXij may include a light emitting element ED and a pixel driving circuit PDC. The pixel PXij may be connected to i-th scan lines SCLi and SSLi among the scan lines SCL1 to SCLn and SSL1 to SSLn, a j-th data line DLj among the data lines DL1 to DLm, and a j-th lead-out line RLj among the lead-out lines RL1 to RLm. The i-th scan lines SCLi and SSLi may include an i-th first scan line SCLi and an i-th second scan line SSLi.

The pixel driving circuit PDC may include a first transistor TR1, a second transistor TR2, a third transistor TR3, and a capacitor Cst. The configuration of the pixel driving circuit PDC according to the present disclosure is not limited to the embodiments illustrated in FIG. 4. The pixel driving circuit PDC illustrated in FIG. 4 is merely an example, and the configuration of the pixel driving circuit PDC may be modified and implemented. For example, the pixel driving circuit PDC may further include at least one transistor and at least one capacitor.

According to some embodiments of the present disclosure, the first transistor TR1, the second transistor TR2, and the third transistor TR3 may each be described as an N-type thin film transistor. However, the embodiments of the present disclosure are not limited thereto. For example, at least one of the first transistor TR1, the second transistor TR2, or the third transistor TR3 may be a P-type thin film transistor.

In addition, the first transistor TR1, the second transistor TR2, and the third transistor TR3 may each be a transistor having an oxide semiconductor layer. However, the embodiments of the present disclosure are not particularly limited thereto. For example, at least one of the first transistor TR1, the second transistor TR2, or the third transistor TR3 may be a transistor having a low-temperature polycrystalline silicon (LTPS) semiconductor layer.

The first transistor TR1 may be electrically connected between a first power line PL1 and the light emitting element ED. The first transistor TR1 may include a gate connected to a first node N1, a first electrode connected to the first power line PL1, and a second electrode connected the light emitting element ED. The light emitting element ED and the first transistor TR1 may be electrically connected to a second node N2. The first power voltage ELVDD may be provided to the pixel PXij through the first power line PL1.

The first transistor T1 may control the amount of current flowing to the light emitting element ED, in correspondence to a voltage of the first node N1. For example, the first transistor TR1 may be turned on when a voltage (i.e., a gate-source voltage) between the first node N1 and the second node N2 is higher than a threshold voltage.

The second transistor TR2 may be electrically connected between the j-th data line DLj and the first node N1. The second transistor TR2 may include a gate electrode connected to the i-th first scan line SCLi, a first electrode connected to the j-th data line DLj, and a second electrode connected to the first node N1.

The second transistor TR2 may transfer a data voltage DS received from the j-th data line DLj to the first node N1, in response to an i-th first scan signal SCi provided to the i-th first scan line SCLi. For example, the second transistor TR2 may be turned on when the i-th first scan signal SCi is at a logic high level.

The third transistor TR3 may be electrically connected between the second node N2 and the j-th lead-out line RLj. The third transistor TR3 may include a gate electrode connected to the i-th second scan line SSLi, a first electrode connected to the j-th lead-out line RLj, and a second electrode connected to the second node N2. The third transistor TR3 may connect the second node N2 to the j-th lead-out line RLj, in response to an i-th second scan signal SSi provided to the i-th second scan line SSLi. For example, the third transistor TR3 may be turned on when the i-th second scan signal SSi is at a logic high level.

According to some embodiments of the present disclosure, during an image display operation, the third transistor TR3 may transfer the initialization voltage Vint to the second node N2 in response to the second scan signal SSi. That is, when the third transistor TR3 is turned on, the second electrode of the first transistor TR1 may be reset to the initialization voltage Vint.

During a sensing operation, the third transistor TR3 may transfer a sensing current corresponding to a voltage of the second node N2 to the j-th lead-out line RLj in response to the second scan signal SSi. The control circuit TC (see FIG. 3) may receive the sensing current to determine a threshold voltage or mobility of the first transistor TR1, and may generate compensated image data RGB.

The capacitor Cst may be connected between the first node N1 and the second node N2. When the data voltage DS is supplied, the initialization voltage Vint may be supplied to the second node N2. In this case, a difference voltage between the data voltage DS and the initialization voltage Vint may be stored in the capacitor Cst. Depending on a voltage stored in the capacitor Cst, whether the first transistor TR1 is turned on or turned off may be determined.

The light emitting element ED may be connected between the second node N2 and a second power line PL2. The second power voltage ELVSS may be applied to the second power line PL2. The light emitting element ED may include a first electrode (e.g., anode), a second electrode (e.g., cathode), and a light emitting layer between the first electrode and the second electrode. For example, the first electrode may be connected to the second node N2, and the second electrode may be connected to the second power line PL2. The light emitting element ED may generate light having a luminance (e.g., a set or predetermined luminance) in correspondence to the amount of current provided from the first transistor TR1.

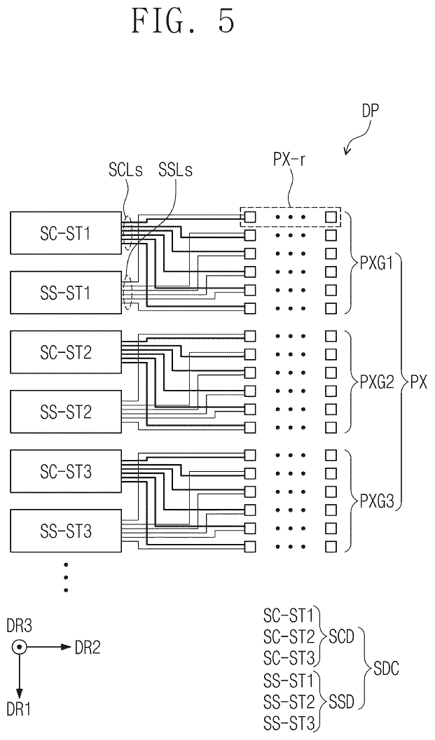

FIG. 5 is a block diagram illustrating some components of the display panel DP according to some embodiments of the present disclosure.

Referring to FIG. 5, a portion of the scan driving circuit SDC and the pixels PX are illustrated. The scan driving circuit SDC may include a first scan driving circuit SCD and a second scan driving circuit SSD. The first scan driving circuit SCD may include a plurality of first-type stages SC-ST1, SC-ST2, and SC-ST3, and the second scan driving circuit SSD may include a plurality of second-type stages SS-ST1, SS-ST2, and SS-ST3.

According to some embodiments of the present disclosure, the first-type stages SC-ST1, SC-ST2, and SC-ST3 may be arranged along the first direction DR1, and the second-type stages SS-ST1, SS-ST2, and SS-ST3 may be arranged along the first direction DR1. In addition, the first-type stages SC-ST1, SC-ST2, and SC-ST3 and the second-type stages SS-ST1, SS-ST2, and SS-ST3 may be alternatively and repeatedly arranged one by one along the first direction DR1.

According to some embodiments of the present disclosure, each of the first-type stages SC to SC-ST1, SC-ST2, and SC-ST3 may be electrically connected to a plurality of first scan lines SCLs. In addition, each of the second-type stages SS-ST1, SS-ST2, and SS-ST3 may be electrically connected to a plurality of second scan lines SSLs. For example, one first-type stage SC-ST1 may be connected to Y first scan lines SCLs and output Y first scan signals, and one second-type stage SS-ST1 may be connected to Y second scan lines SSLs and output Y second scan signals. Y may be an integer of 2 or greater.

Although FIG. 5 illustrates an example in which one first-type stage SC-ST1 is electrically connected to six first scan lines SCLs, and one second-type stage SS-ST1 is electrically connected to six second scan lines SSLs, the embodiments of the present disclosure are not limited thereto. For example, two or more first scan lines SCLs may be connected to one first-type stage SC-ST1, and two or more second scan lines SS-ST1 may be connected to one second-type stage SS-ST1.

According to some embodiments of the present disclosure, the plurality of pixels PX may be arranged in the first direction DR1 and the second direction DR2. Among the plurality of pixels PX, one row of pixels PX-r (hereinafter, referred to as a pixel row) arranged in the second direction DR2 may be connected to one first-type stage SC-ST1 and one second-type stage SS-ST1. In addition, the pixels PX include Y row(s) of pixels PXG1 (hereinafter, referred to as first pixel groups) arranged in the first direction DR1, and the first pixel groups PXG1 may be connected to one first-type stage SC-ST1 and one second-type stage SS-ST1.

A first pixel groups PXG1 including six pixel rows PX-r may be connected to a first first-type stage SC-ST1 and a first second-type stage SS-ST1. A second pixel groups PXG2 including next six pixel rows PX-r may be connected to a second first-type stage SC-ST2 and a second second-type stage SS-ST2. A third pixel groups PXG3 including next six pixel rows PX-r may be connected to a third first-type stage SC-ST3 and a third second-type stage SS-ST3.

According to some embodiments of the present disclosure, one stage, for example, the first-type stage SC-ST1 may control the operation of a pixel group including two or more pixel rows PPX-r, for example, the operation of the first pixel group PXG1. That is, the total number of stages may be less than the number of rows of the pixels PX. Accordingly, the number of transistors, capacitors, and lines (e.g., clock lines) located in the non-display region NDA (see FIG. 3) may be relatively reduced. As a result, the width of the non-display region NDA (see FIG. 3) of the display panel DP (see FIG. 2) may be relatively reduced.

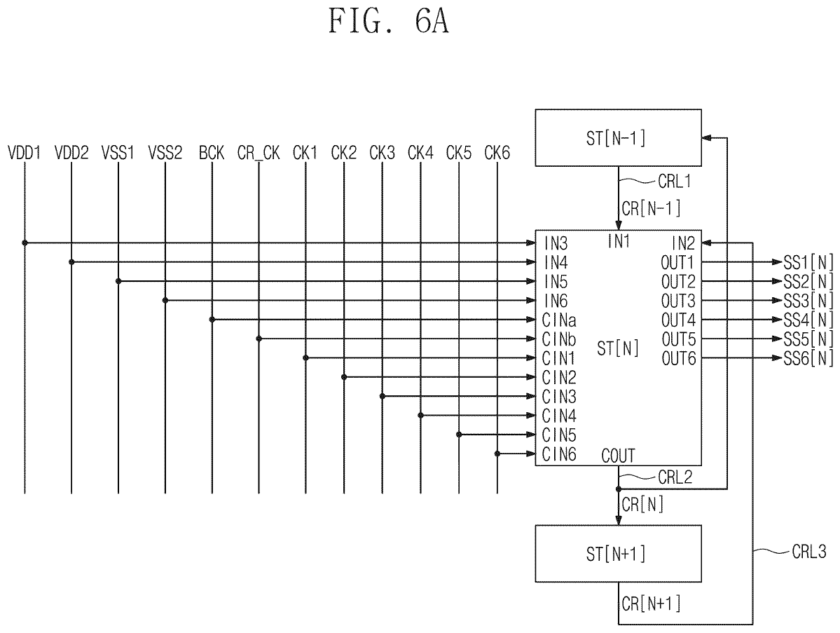

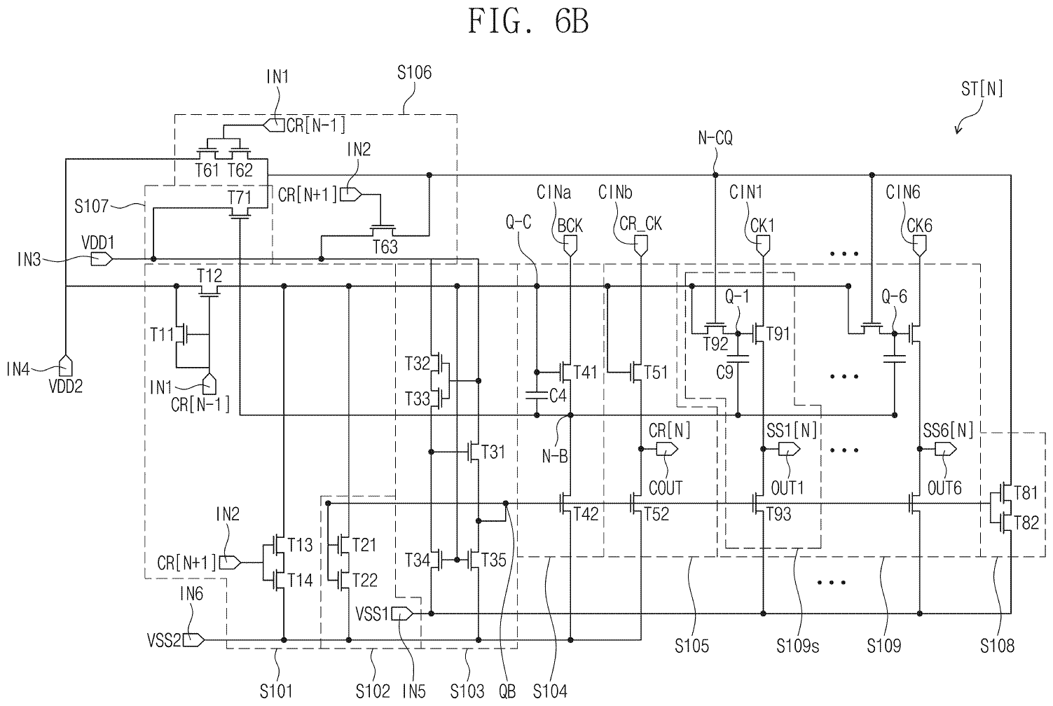

FIG. 6A is a view illustrating the scan driving circuit SDC according to some embodiments of the present disclosure. FIG. 6B is an equivalent circuit diagram illustrating one stage ST[N] according to some embodiments of the present disclosure. Although FIG. 6B illustrates various components in a stage according to some embodiments, embodiments according to the present disclosure are not limited thereto, and according to various embodiments, the stage may include additional components or fewer components without departing from the spirit and scope of embodiments according to the present disclosure.

FIG. 6A illustrates three stages ST[N−1], ST[N], and ST[N+1] as an example. N may be an integer of 2 or greater. The three stages ST[N−1], ST[N], and ST[N+1] may be the first-type stages SC-ST1, SC-ST2, SC-ST3 (see FIG. 5), or the second-type stages SS-ST1, SS-ST2, and SS-ST3 (see FIG. 5).

FIG. 6B illustrates an equivalent circuit diagram of one stage ST[N] as an example. Because the rest of the stages ST[N−1] and ST[N+1] have substantially the same configuration, redundant descriptions thereof will be omitted. The configuration of one stage ST[N] according to the present disclosure is not limited to the embodiments illustrated in FIG. 6B. One stage ST[N] illustrated in FIG. 6B is merely an example, and the circuit configuration of one stage ST[N] may be modified and implemented.

Referring to FIG. 6A, the stages ST[N−1], ST[N], and ST[N+1] may be sequentially referred to as a first stage ST[N−1], a second stage ST[N], and a third stage ST[N+1]. Alternatively, the second stage ST[N] may be referred to as a reference stage or a stage, the first stage ST[N−1] may be referred to as a first peripheral stage, and the third stage SST[N+1] may be referred to as a second peripheral stage. Hereinafter, the second stage ST[N] is referred to as a stage.

The stage ST[N] may include first to sixth input terminals IIN1, IN2, IN3, IN4, IN5, and IN6, first to sixth clock terminals CIN1, CIN2, CIN3, CIN4, CIN5, and CIN6, a first control terminal CINa, a second control terminal CINb, first to sixth output terminals OUT1, OUT2, OUT3, OUT4, OUT5, and OUT6, and a carry output terminal COUT.

The first input terminal IN1 of the stage ST[N] may receive a carry signal CR[N−1] output from the previous stage, for example, the first stage ST[N−1]. If the stage ST[N] is the first stage, the first input terminal IN1 may receive a start signal output from a dummy stage before the first stage.

The carry signal CR[N−1] may be referred to as a previous carry signal or a first carry signal, and hereinafter, is referred to as the first carry signal CR[N−1]. The first stage ST[N−1] and the stage ST[N] may be electrically connected to a first carry line CRL1, and the first carry line CRL1 may be referred to as a first peripheral carry line. The first carry signal CR[N−1] generated in the first stage ST[N−1] may be transferred to the stage ST[N] through the first carry line CRL1.

The second input terminal IN2 of the stage ST[N] may receive a carry signal CR[N+1] output from following stage, for example, the third stage ST[N+1]. If the stage ST[N] is the last stage, the second input terminal IN2 may receive a carry signal output from a dummy stage after the last stage.

The carry signal CR[N+1] may be referred to as a next carry signal or a third carry signal, and hereinafter, is referred to as the third carry signal CR[N+1]. The third stage ST[N+1] and the stage ST[N] may be electrically connected to a third carry line CRL3, and the third carry line CRL3 may be referred to as a second peripheral carry line. The third carry signal CR[N+1] generated in the third stage ST[N+1] may be transferred to the stage ST[N] through the third carry line CRL3.

A third input terminal IN3 of the stage ST[N] may be supplied with a first high voltage VDD1, and a fourth input terminal IN4 may be supplied with a second high voltage VDD2. The voltage level of the second high voltage VDD2 may be greater than the voltage level of the first high voltage VDD1, but the embodiments of the present disclosure are not limited thereto. For example, the first high voltage VDD1 may be 15 V, and the second high voltage VDD2 may be 25 V.

A fifth input terminal IN5 of the stage ST[N] may be supplied with a first low voltage VSS1, and a sixth input terminal IN6 may be supplied with a second low voltage VSS2. The voltage level of the first low voltage VSS1 and the voltage level of the second low voltage VSS2 may be the same as or different from each other.

The stage ST[N] may receive a boost clock signal BCK through the first control terminal CINa, and may receive a carry clock signal CR_CK through the second control terminal CINb. The stage ST[N] may receive first to sixth clock signals CK1, CK2, CK3, CK4, CK5, and CK6 through the first to sixth clock terminals CIN1, CIN2, CIN3, CIN4, and CIN5, CIN6. According to some embodiments of the present disclosure, the first to sixth clock terminals CIN1, CIN2, CIN3, CIN4, CIN5, and CIN6 of each of the first stage ST[N−1 and the third stage ST[N+1] may respectively receive clock signals having an inverted phase with the first to sixth clock signals CK1, CK2, CK3, CK4, CK5, and CK6.

The carry output terminal COUT of the stage ST[N] may output a carry signal CR[N]. The carry signal CR[N] may be transferred to the first stage ST[N−1] and the third stage ST[N+1]. The carry signal CR[N] may be referred to as a second carry signal, and hereinafter, is referred to as a second carry signal CR[N]. The first stage ST[N−1], the stage ST[N], and the third stage ST[N+1] may be electrically connected to a second carry line CRL2. The second carry signal CR[N] generated in the stage ST[N] may be transferred to the first stage ST[N−1] and the third stage ST[N+1] through the second carry line CRL2.

The first to sixth output terminals OUT1, OUT2, OUT3, OUT4, OUT5, and OUT6 of the stage ST[N] may respectively output first to sixth scan signals SS1[N], SS2[N], SS3[N], SS4[N], SS5[N], and SS6[N]. The first to sixth scan signals SS1[N], SS2[N], SS3[N], SS4[N], SS5[N], and SS6[N] may be, for examples, respectively provided to pixels of six rows in the second pixel group PXG2.

The first to sixth scan signals SS1[N], SS2[N], SS3[N], SS4[N], SS5[N], SS6[N] may be first scan signals (or first-type scan signals) respectively provided through the first scan lines SCLs (see FIG. 5). Alternatively, the first to sixth scan signals SS1[N], SS2[N], SS3[N], SS4[N], SS5[N], SS6[N] may be second scan signals (or second-type scan signals) respectively provided through the second scan lines SSLs (see FIG. 5).

Referring to FIG. 6B, one stage ST[N] may include a first node Q-C, a second node QB, a third node N-CQ, a fourth node N-B, and a plurality of split nodes Q-1 to Q-6. The first node Q-C may be referred to as a Q node, the plurality of split nodes Q-1 to Q-6 may be referred to as split Q nodes, and the second node QB may be referred to as a QB node.

In addition, one stage ST[N] may further include a first circuit S101, a second circuit S102, a third circuit S102, a fourth circuit S104, a fifth circuit S105, a sixth circuit S106, a seventh circuit S107, an eighth circuit S108, and a ninth circuit S109.

The first circuit S101 may control a voltage of the first node Q-C, and may be referred to as a first node control circuit. The first circuit S101 may include first to fourth transistors T11, T12, T13, and T14.

The first transistor T11 and the second transistor T12 may be connected in series to each other, and the first and second transistors T11 and T12 may have a dual gate structure. The first transistor T11 and the second transistor T12 may be connected between the first input terminal IN1 and the first node Q-C. In addition, a gate electrode of the first transistor T11 and a gate electrode of the second transistor T12 may be both connected to the first input terminal IN1. The fourth input terminal IN4 may be connected between the first transistor T11 and the second transistor T12. The first and second transistors T11 and T12 may be turned on in response to a gate on-voltage (e.g., a logic high level) of the first carry signal CR[N−1], and the second transistor T12 may transfer the second high voltage VDD2 to the first node Q-C. An operation of transferring the second high voltage VDD2 to the first node Q-C may be referred to as a pre-charging operation or a primary boosting operation. The third transistor T13 and the fourth transistor T14 may be connected in series to each other, and the third and fourth transistors T13 and T14 may have a dual gate structure. The third and fourth transistors T13 and T14 may be connected between the first node Q-C and the sixth input terminal IN6. In addition, a gate electrode of the third transistor T13 and a gate electrode of the fourth transistor T14 may be both connected to the second input terminal IN2. The third and fourth transistors T13 and T14 may transfer the second low voltage VSS2 to the first node Q-C in response to a gate on-voltage (e.g., a logic high level) of the third carry signal CR[N+1].

The second circuit S102 may include a first transistor T21 and a second transistor T22. The first transistor T21 and the second transistor T22 may be connected in series to each other, and the first and second transistors T21 and T22 may be connected between the first node Q-C and the sixth input terminal IN6. In addition, a gate electrode of the first transistor T21 and a gate electrode of the second transistor T22 may be both connected to the second node QB. The first and second transistors T21 and T22 may transfer the second low voltage VSS2 to the first node Q-C in response to a voltage of the second node QB. Therefore, the second circuit S102 may be referred to as a first node stabilization circuit.

The third circuit S103 may include a first transistor T31, a second transistor T32, a third transistor T33, a fourth transistor T34, and a fifth transistor T35.

The first transistor T31 may be connected between the second node QB and the third input terminal IN3. The second transistor T32 and the third transistor T33 may be connected in series to each other, gate electrodes of the second and third transistors T32 and T33 may be connected to the third input terminal IN3, and the second and third transistors T32 and T33 may be connected between the third input terminal IN3 and the gate electrode of the first transistor T31.

The fourth transistor T34 may be connected between the gate electrode of the first transistor T31 and the fifth input terminal IN5, and the fifth transistor T35 may be connected between the second node QB and the sixth input terminal IN6. The gate electrode of the fourth transistor T34 and a gate electrode of the fifth transistor T35 may be connected to the first node Q-C.

The second and third transistors T32 and T33 transfer the first high voltage VDD1 to the gate electrode of the first transistor T31 in response to the first high voltage VDD1. The operation of the fourth transistor T34 is controlled in response to the voltage of the first node Q-C. When the fourth transistor T34 is turned on, the first low voltage VSS1 may be transferred to the gate electrode of the first transistor T31.

The first transistor T31 may transfer the first high voltage VDD1 to the second node QB in response to a voltage of the gate electrode of the first transistor T31. The operation of the fifth transistor T35 is controlled in response to the voltage of the first node Q-C. When the fifth transistor T35 is turned on, the second low voltage VSS2 may be transferred to the second node QB.

The fourth circuit S104 may include a first transistor T41, a second transistor T42, and a capacitor C4.

The first transistor T41 may be connected between the first control terminal CINa and the fourth node N-B. A gate electrode of the first transistor T41 may be connected to the first node Q-C. The operation of the first transistor T41 is controlled in response to the voltage of the first node Q-C. When the first transistor T41 is turned on, a logic high-level voltage may be provided to the fourth node N-B.

The second transistor T42 may be connected between the fourth node N-B and the sixth input terminal IN6. A gate electrode of the second transistor T42 may be connected to the second node QB. The operation of the second transistor T42 is controlled in response to the voltage of the second node QB. When the second transistor T42 is turned on, the second low voltage VSS2 may be provided to the fourth node N-B.

The capacitor C4 is connected to the gate electrode of the first transistor T41 and the fourth node N-B. The capacitor C4 may increase (boost up) the voltage of the first node Q-C in response to an increase in voltage of the fourth node N-B, which may be referred to as a secondary boosting operation.

The fifth circuit S105 may include a first transistor T51 and a second transistor T52.

The first transistor T51 may be connected between the second control terminal CINb and the carry output terminal COUT. A gate electrode of the first transistor T51 may be connected to the first node Q-C. The operation of the first transistor T51 is controlled in response to the voltage of the first node Q-C. When the first transistor T51 is turned on, a logic high-level voltage of the second carry signal CR[N] may be provided to the carry output terminal COUT.

The second transistor T52 may be connected between the carry output terminal COUT and the sixth input terminal IIN6. A gate electrode of the second transistor T52 may be connected to the second node QB. The operation of the second transistor T52 is controlled in response to the voltage of the second node QB. When the second transistor T52 is turned on, the second low voltage VSS2 may be provided to the carry output terminal COUT.

The sixth circuit S106 may control a voltage of the third node N-CQ, and may be referred to as a third node control circuit. The sixth circuit S106 may include a first transistor T61, a second transistor T62, and third transistor T63.

The first transistor T61 and the second transistor T62 may be connected in series to each other, and the first and second transistors T61 and T62 may have a dual gate structure. The first transistor T61 and the second transistor T62 may be connected between the fourth input terminal IN4 and the third node N-CQ. In addition, a gate electrode of the first transistor T61 and a gate electrode of the second transistor T612 may be both connected to the first input terminal IN1. The first and second transistors T61 and T62 may transfer the second low voltage VDD2 to the third node N-CQ in response to a gate on-voltage (e.g., a logic high level) of the first carry signal CR[N−1].

The third transistor T63 may be connected between the third node N-CQ and the third input terminal IN3. In addition, a gate electrode of the third transistor T63 may be connected to the second input terminal IN2. The third transistor T63 may transfer the first high voltage VDD1 to the third node N-CQ in response to a gate on-voltage (e.g., a logic high level) of the third carry signal CR[N+1].

The seventh circuit S107 may include a transistor T71. The transistor T71 may be connected between the third input terminal IN3 and the third node N-CQ. A gate electrode of the transistor T71 may be connected to the fourth node N-B. The transistor T71 may provide the first high voltage VDD1 to the third node N-CQ in response to the voltage of the fourth node N-B.

The eighth circuit S108 may include a first transistor T81 and a second transistor T82.

The first transistor T81 and the second transistor T82 may be connected in series to each other, and the first and second transistors T81 and T82 may be connected between the third node N-CQ and the fifth input terminal IN5. In addition, a gate electrode of the first transistor T81 and a gate electrode of the second transistor T82 may be both connected to the second node QB. The first and second transistors T81 and T82 may transfer the first low voltage VSS1 to the third node N-CQ in response to the voltage of the second node QB. Therefore, the eighth circuit S108 may be referred to as a third node stabilization circuit.

The ninth circuit S109 may include a plurality of output circuits S109s. According to some embodiments of the present disclosure, because one stage ST[N] outputs six scan signals, the ninth circuit S109 may include six output circuits S109s. FIG. 6B illustrates an example first output circuit and a last output circuit (e.g., a sixth output circuit), a total of two output circuits.

The output circuits S109s may each include a first transistor T91, a second transistor T92, a third transistor T93, and a capacitor C9. Hereinafter, the first output circuit S109s is described, and because the rest of the output circuits S109s include substantially the same configuration, redundant descriptions thereof will be omitted.

The first transistor T91 may be connected between a first clock terminal CIN1 and a first output terminal OUT1. A gate electrode of the first transistor T91 may be connected to a split node Q-1. The second transistor T92 may be connected between the first node Q-C and the split node Q-1. A gate electrode of the second transistor T92 may be connected to the third node N-CQ. The second transistor T92 may connect the first node Q-C to the split node Q-1, or separate the first node Q-C from the split node Q-1, in response to the voltage of the third node N-CQ.

The operation of the first transistor T91 is controlled in response to a voltage of the split node Q-1. When the first transistor T91 is turned on, a logic high-level voltage of the scan signal SS1[N] may be provided to the first output terminal OUT1.

According to some embodiments of the present disclosure, the transistor T71 may be turned on at the timing at which the fourth node N-B is boosted, and may transfer the first high voltage VDD1 to the third node N-CQ. The voltage of the first node Q-C at the timing at which the fourth node N-B is boosted may be higher than the first high voltage VDD1 of the third node N-CQ. Therefore, the second transistor T92 may be turned off. The second transistor T92 may separate the first node Q-C from the split node Q-1 in response to the voltage of the third node N-CQ.

While a signal is output to the first to sixth output terminals OUT1, OUT2, OUT3, OUT4, OUT5, and OUT6, the first node Q-C and the split node Q-1 may be electrically separated from each other, and the splits nodes Q-1 to Q-6 may also be electrically separated from each other. Therefore, even if the voltage of the split node Q-1 is coupled and changed according to the signal output to the first output terminal OUT1, the impact on other nodes may be eliminated. For example, the other nodes may be the first node Q-C and the rest of the split nodes except for the split node Q-1 among the first node Q-C and the split nodes Q-1 to Q-6. Therefore, horizontal line defects due to the difference in luminance for each line may be eliminated.

According to some embodiments of the present disclosure, when the second low voltage VSS2 is transferred to the first node Q-C in response to the gate on-voltage of the third carry signal CR[N+1], the voltage of the first node Q-C may be lower than the voltage of the third node N-CQ. In this case, the second transistor T92 may be turned on to connect the first node Q-C to the split node Q-1, and the split node Q-1 may be discharged.

The third transistor T93 may be connected between the first output terminal OUT1 and the fifth input terminal IN5. A gate electrode of the third transistor T93 may be connected to the second node QB. The operation of the third transistor T93 is controlled in response to the voltage of the second node QB. When the third transistor T93 is turned on, the first low voltage VSS1 may be provided to the first output terminal OUT1.

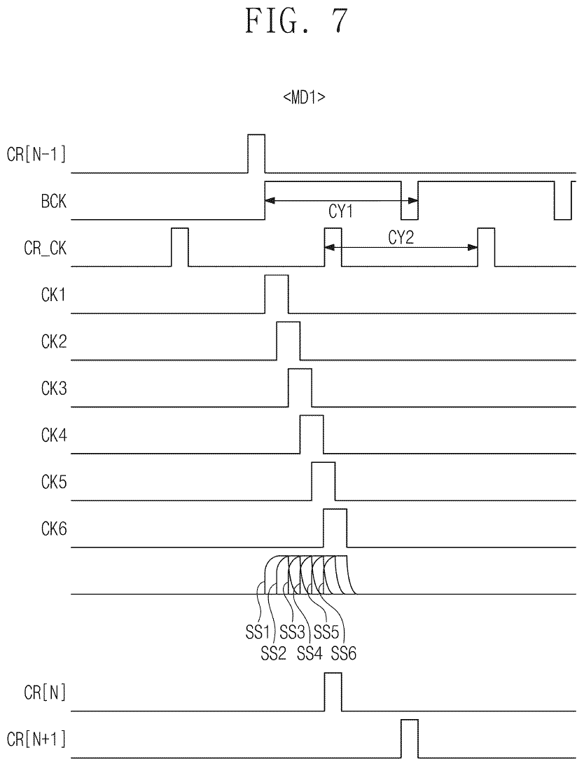

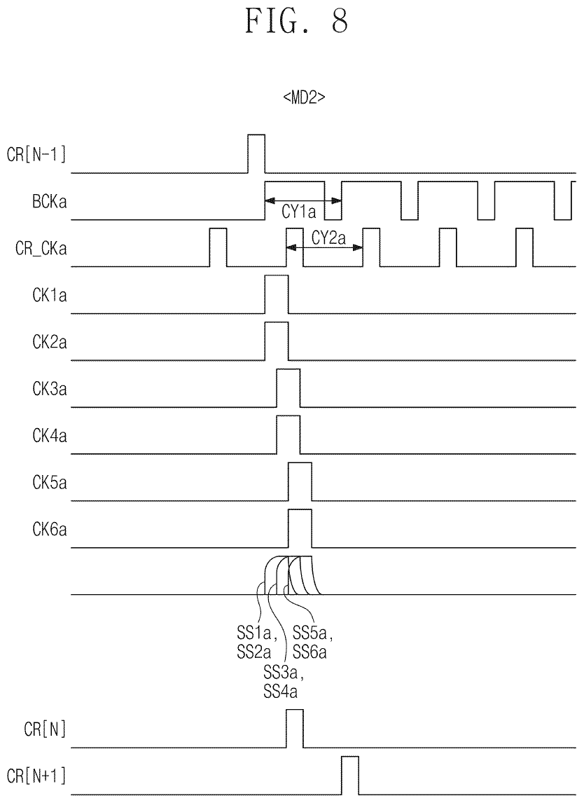

The capacitor C9 is connected to the split node Q-1 and the fourth node N-B. The capacitor C9 may increase (boost up) the voltage of the split node Q-1 in correspondence to the increase in the voltage of the fourth node N-B. If the voltage of the split node Q-1 increases, the scan signal SS1[N] having a high voltage may be output without distortion. FIG. 7 is a timing diagram for describing an operation of a stage in a first mode MD1 according to some embodiments of the present disclosure. FIG. 8 is a timing diagram of a plurality of clock signals for describing an operation of a stage in a second mode MD2 according to some embodiments of the present disclosure.

Referring to FIG. 1, FIG. 7, and FIG. 8 together, the display panel DP may be selectively operated in the first mode MD1 or the second mode MD2. For example, the first mode MD1 may be a normal driving mode driven at a first frequency, and the second mode MD2 may be a high-frequency driving mode driven at a second frequency higher than the first frequency. For example, the first frequency may be 240 Hz, and the second frequency may be 480 Hz. However, the first frequency and the second frequency described above are merely an example, and the first and second frequencies are not particularly limited to the above-described example.

Referring to FIG. 7, the first carry signal CR[N−1], the second carry signal CR[N], the third carry signal CR[N+1], the boost clock signal BCK, the carry clock signal CR_CK, and the first to sixth clock signals CK1, CK2, CK3, CK4, CK5, and CK6 in the first mode MD1 are illustrated.

Referring to FIG. 8, the first carry signal CR[N−1], the second carry signal CR[N], the third carry signal CR[N+1], a boost clock signal BCKa, a carry clock signal CR_CKa, and first to sixth clock signals CK1a, CK2a, CK3a, CK4a, CK5a, and CK6a in the second mode MD2 are illustrated.

Referring to FIG. 7 and FIG. 8 together, in the first mode MD1, a period CY1 of the boost clock signal BCK may be longer than a period CY1a of the boost clock signal BCK in the second mode MD2. For example, the period CY1 may be twice as long as the period CY1a. In addition, in the first mode MD1, a period CY2 of the carry clock signal CR_CK may be longer than a period CY2a of the carry clock signal CR_CK in the second mode MD2. For example, the period CY2 may be twice as long as the period CY2a. That is, the period of the clocks may be reduced in the second mode MD2.

According to some embodiments of the present disclosure, at least some of the plurality of scan lines may be simultaneously driven (e.g., activated) for low-power driving or high-speed driving. For example, two scan lines may be simultaneously driven, and the second mode MD2 may be referred to as a dual-line gate driving mode. According to some embodiments of the present disclosure, the first mode MD1 may be a high resolution mode, and the second mode MD2 may be a high scan rate mode.

In the first mode MD1, the first to sixth clock signals CK1, CK2, CK3, CK4, CK5, and CK6 may have different phases. That is, the first to sixth clock signals CK1, CK2, CK3, CK4, CK5, and CK6 may have waveforms shifted from each other by an interval (e.g., a set or predetermined interval). In correspondence thereto, first to sixth scan signals SS1, SS2, SS3, SS4, SS5, and SS6 output in synchronization with the first to sixth clock signals CK1, CK2, CK3, CK4, CK5, and CK6 may have different phases from each other. The first to sixth scan signals SS1, SS2, SS3, SS4, SS5, and SS6 may be referred to as first mode scan signals.

The first to sixth scan signals SS1, SS2, SS3, SS4, SS5, and SS6 may be first scan signals (or referred to as first-type scan signals) respectively provided through the first scan lines SCLs (see FIG. 5). Alternatively, the first to sixth scan signals SS1, SS2, SS3, SS4, SS5, and SS6 may be second scan signals (or referred to as second-type scan signals) respectively provided through the second scan lines SSLs (see FIG. 5).

In the second mode MD2, some clock signals among the first to sixth clock signals CK1a, CK2a, CK3a, CK4a, CK5a, and CK6a may have the same phase. For example, waveforms of the first clock signal CK1a and the second clock signal CK2a may be the same as each other. The third clock signal CK3a may have a waveform shifted by a time (e.g., a set or predetermined time) with respect to the first clock signal CK1a, and waveforms of the third clock signal CK3a and the fourth clock signal CK4a may be the same as each other. In addition, waveforms of the fifth clock signal CK5a and the sixth clock signal CK6a may be the same as each other.

In the second mode MD2, some of first to sixth scan signals SS1a, SS2a, SS3a, SS4a, SS5a, and SS6a output in synchronization with the first to sixth clock signals CK1a, CK2a, CK3a, CK4a, CK5a, and CK6a may have waveforms which have the same phase as each other. For example, the first scan signal SS1a and the second scan signal SS2a may overlap each other and may have substantially the same waveform. In this case, in the second mode MD2, a data voltage DS (see FIG. 6B) may be simultaneously provided to one row of pixels which receive the first scan signal SS1a and one row of pixels which receive the second scan signal SS2a.

The third scan signal SS3a and the fourth scan signal SS4a may overlap each other and may have substantially the same waveform. The fifth scan signal SS5a and the sixth scan signal SS6a may overlap each other and may have substantially the same waveform. The first to sixth scan signals SS1a, SS2a, SS3a, SS4a, SS5a, and SS6a may be referred to as second mode scan signals.

The first to sixth scan signals SS1a, SS2a, SS3a, SS4a, SS5a, and SS6a may be first scan signals (or referred to as first-type scan signals) respectively provided through the first scan lines SCLs (see FIG. 5). Alternatively, the first to sixth scan signals SS1a, SS2a, SS3a, SS4a, SS5a, and SS6a may be second scan signals (or referred to as second-type scan signals) respectively provided through the second scan lines SSLs (see FIG. 5).

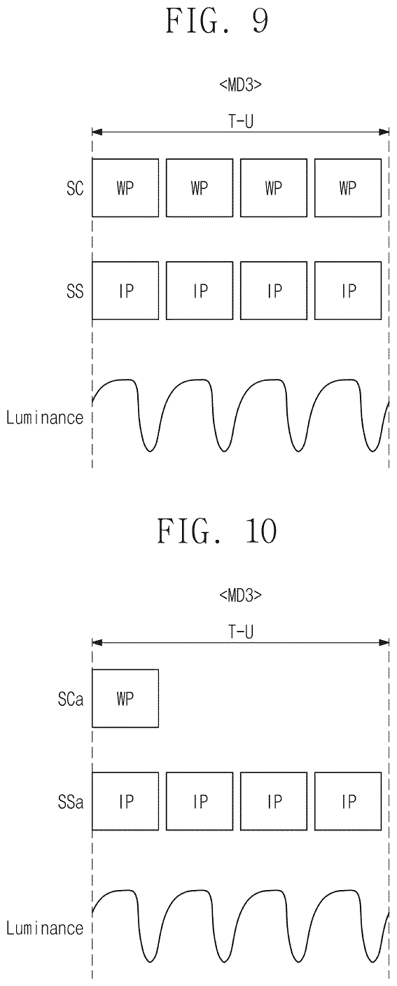

FIG. 9 is a view illustrating an activation state of a first scan signal SC and a second scan signal SS and changes in luminance according to some embodiments of the present disclosure. FIG. 10 is a view illustrating an activation state of a first scan signal SCa and a second scan signal SSa and changes in luminance according to some embodiments of the present disclosure. The first scan signal SC and the first scan signal SCa may be signals provided to the i-th first scan line SCLi illustrated in FIG. 4, and the second scan signal SS and the second scan signal SSa may be signals provided to the i-th second scan line SSLi illustrated in FIG. 4.

Referring to FIG. 1, FIG. 9, and FIG. 10, the display panel DP may operate in a mode (hereinafter, a third mode) driven at a variable frame frequency. For example, the variable frame frequency may be variously modified within the range of 1 Hz to 240 Hz, but the embodiments of the present disclosure are not limited thereto. FIG. 9 illustrates am example luminance of the first scan signal SC, the second scan signal SS, and the display panel DP when driven at 240 Hz, and FIG. 10 illustrates an example luminance of the first scan signal SCa, the second scan signal SSa, and the display panel DP when driven at 60 Hz.

Referring to FIG. 9 and FIG. 10, when the display panel DP is driven at 240 Hz, during a unit time T-U, the first scan signal SC may include four write cycle periods WP, and the second scan signal SS may include four initialization cycle periods IP. In addition, when the display panel DP is driven at 60 Hz, during the unit time T-U, the first scan signal SCa may include one write cycle period WPa, and the second scan signal SSa may include four initialization cycle periods IP.

In the write cycle period WP or WPa, the first scan signal SC or SCa may have a waveform in which a logic high level and a logic low level are alternately repeated, and in the remaining period except for the write cycle period WP or WPa, the first scan signal SC or SCa may have a logic low level. In addition, in the initialization cycle periods IP, the second scan signal SS or SSa may have a waveform in which a logic high level and a logic low level are alternately repeated.

Referring to FIG. 5 together, a plurality of the first-type stages SC-ST1, SC-ST2, and SC-ST3 of the first scan driving circuit SCD which generates the first scan signal SC or SCa and a plurality of the second-type stages SS-ST1, SS-ST2, and SS-ST3 of the second scan driving circuit SSD may be separated from each other. Therefore, the operation of the first scan signal SC or SCa and the operation of the second scan signal SS or SSa may be separated from each other. As a result, the number of initialization cycle periods IP may be adjusted within the unit time T-U regardless of the operating frequency of the display panel DP. In this case, the difference in optical waveforms according to the operating frequency of the display panel DP may be reduced, and as a result, the difference in luminance according to the operating frequency of the display panel DP may be reduced. That is, the display panel DP may have relatively improved image display quality.

The driving modes described with reference to FIG. 7, FIG. 8, FIG. 9, and FIG. 10 may be applied to the display panel DP in various combinations. For example, according to some embodiments of the present disclosure, the display panel DP may operate in one of the first mode MD1, the second mode MD2, and a third mode MD3. The first mode MD1 may correspond to a mode driven at 240 Hz in the third mode MD3. Alternatively, according to some embodiments of the present disclosure, the display panel DP may operate in one of the first mode MD1 and the third mode MD3. In this case, the first mode MD1 may be a normal driving mode driven at a fixed frequency, and the third mode MD3 may be a variable driving mode driven at a variable frequency. Alternatively, according to some embodiments of the present disclosure, the display panel DP may operate in one of the first mode MD1 and the second mode MD2. Alternatively, according to some embodiments of the present disclosure, the display panel DP may operate only in the first mode MD1. Alternatively, according to some embodiments of the present disclosure, the display panel DP may operate only in the third mode MD3.

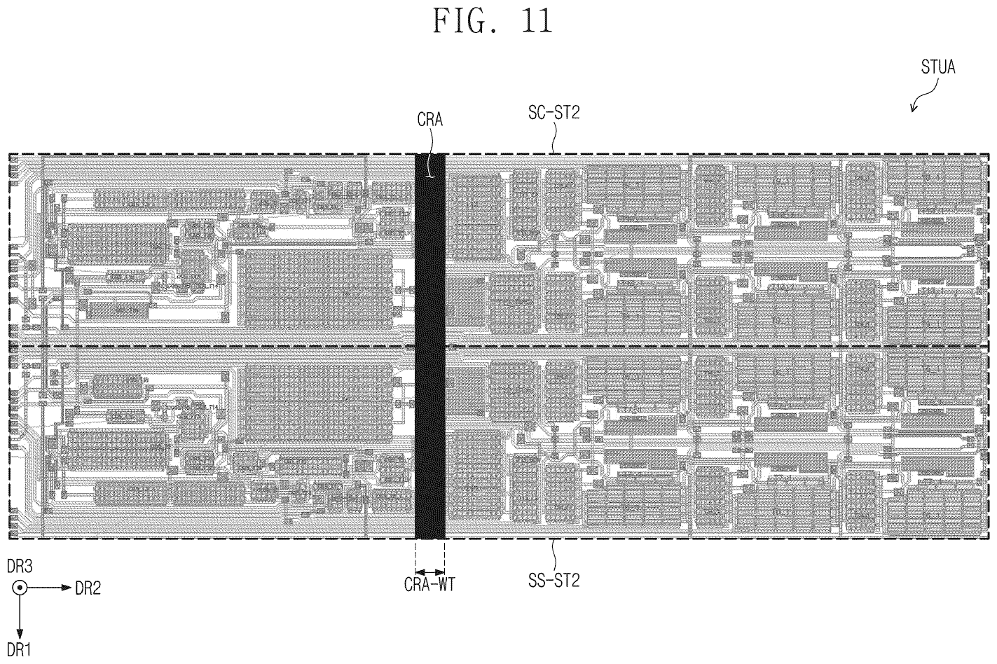

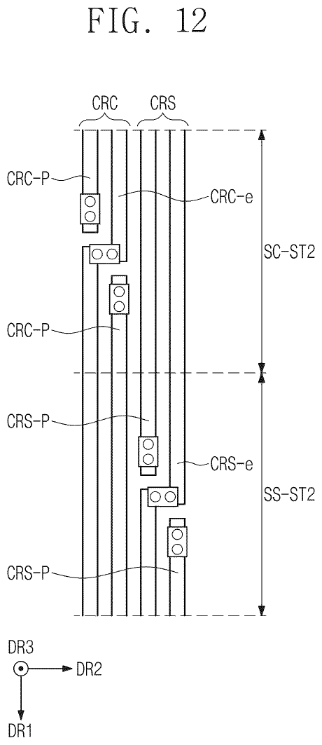

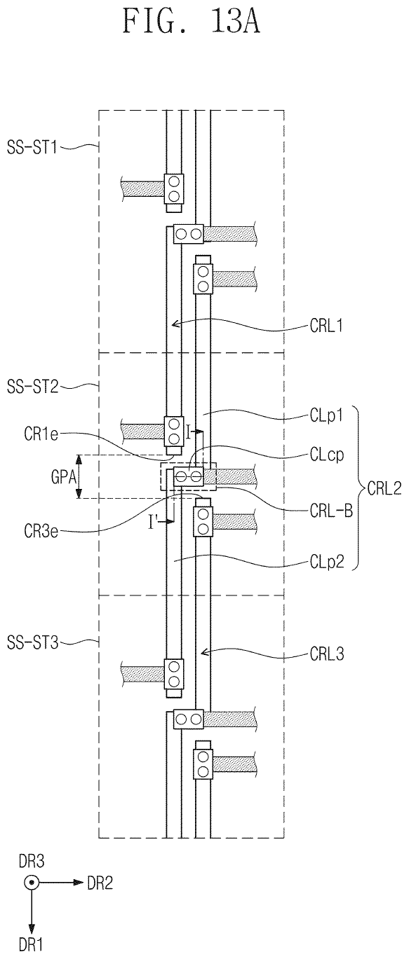

FIG. 11 is a view illustrating one group stage region STUA according to some embodiments of the present disclosure. FIG. 12 is a plan view illustrating a plurality of carry lines CRC and CRS located in a line region CRA illustrated in FIG. 11.

Referring to FIG. 5, FIG. 11, and FIG. 12, in one group stage region STUA, one first-type stage SC-ST2 (hereinafter, referred to as a first-type stage) among the plurality of first-type stages SC-ST1, SC-ST2, and SC-ST3 of the first scan driving circuit SCD and one second-type stage SS-ST2 (hereinafter, referred to as a second-type stage) among the plurality of second-type stages SS-ST1, SS-ST2, and SS-ST3 of the second scan driving circuit SSD may be arranged.

One group stage region STUA may include the line region CRA in which the plurality of carry lines CRC and CRS are located. The carry lines CRC and CRS may include three first-type carry lines CRC connected to the first-type stage SC-ST2 and three second-type carry lines CRS connected to the second-type stage SS-ST2.

According to some embodiments of the present disclosure, ends of two first-type carry lines CRC-p among the three first-type carry lines CRC may overlap the first-type stage SC-ST2, and ends of two second-type carry lines CRS-p among the three second-type carry lines CRS may overlap the second-type stage SS-ST2.

According to some embodiments of the present disclosure, the two first-type carry lines CRC-p may be spaced apart from each other when viewed in the second direction DR2 in a region in which the first-type stage SC-ST2 is located. The remaining first-type carry line CRC-e may be designed to pass between the ends of the two first-type carry lines CRC-p. In addition, the two second-type carry lines CRS-p may be spaced apart from each other when viewed in the second direction DR2 in a region in which the second-type stage SS-ST2 is located. The remaining second-type carry line CRS-e may be designed to pass between the ends of the two second-type carry lines CRS-p. In this case, the number of carry lines located in the wiring line CRA of one group stage region STUA may be six, but the number of carry lines arranged in the second direction DR2 may be four.

According to some embodiments of the present disclosure, a width CRA-WT of the line region in the second direction DR2 may be relatively reduced. Accordingly, the width of the non-display region NDA (see FIG. 2) of the display panel DP (see FIG. 2) may be relatively reduced.

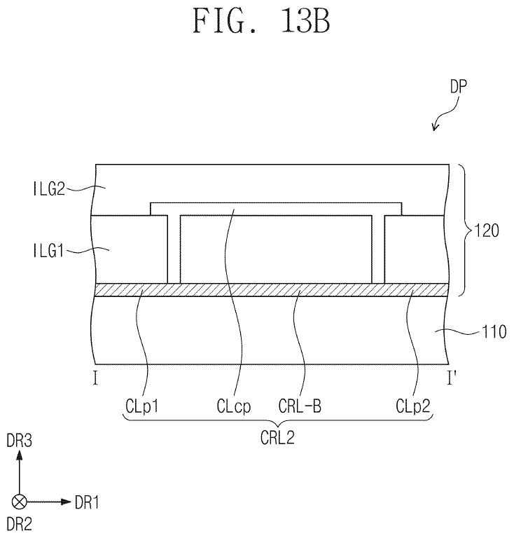

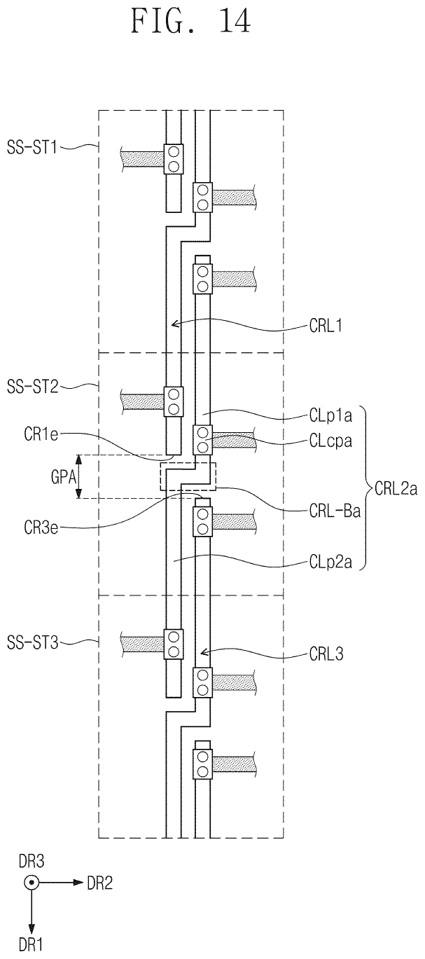

FIG. 13A is a plan view illustrating a plurality of carry lines CRL1, CRL2, and CRL3 according to some embodiments of the present disclosure. FIG. 13B is a cross-sectional view taken along the line I-I′ illustrated in FIG. 13A.

Referring to FIG. 13A, three second-type stages SS-ST1, SS-ST2, and SS-ST3 arranged along the first direction DR1 and three carry lines CRL1, CRL2, and CRL3 connected thereto are illustrated.

The second-type stages SS-ST1, SS-ST2, and SS-ST3 are referred to as a first stage SS-ST1, a second stage SS-ST2, and a third stage SS-ST3 in the description below with reference to FIG. 13A, and the carry lines CRL1, CRL2, and CRL3 are referred to as a first carry line CRL1, a second carry line CRL2, and a third carry line CRL3 in the description below with reference to FIG. 13A and FIG. 13B.

According to some embodiments of the present disclosure, the first stage SS-ST1 may be an X−1-th stage, the second stage SS-ST2 may be an X-th stage, and the third stage SS-ST3 may be an X+1-th stage. X may be an integer of 2 or greater.

The first carry line CRL1 may be connected to the first stage SS-ST1 and the second stage SS-ST2. The second carry line CRL2 may be connected to the first stage SS-ST1, the second stage SS-ST2, and the third stage SS-ST3. The third carry line CRL3 may be connected to the second stage SS-ST2, and the third stage SS-ST3.

According to some embodiments of the present disclosure, a first end CR1e of the first carry line CRL1 and a second end CR3e of the third carry line CRL3 may overlap the second stage SS-ST2. The first end CR1e and the second end CR3e may be spaced apart from each other in the second direction DR2 while not overlapping each other. Therefore, the first carry line CRL1 and the third carry line CRL3 may not overlap each other in the second direction DR2.

The second carry line CRL2 may include a first line portion CLp1, a second line portion CLp2 electrically connected to the first line portion CLp1, and a curved portion CRL-B. The first line portion CLp1, the curved portion CRL-B, and the second line portion CLp2 may be connected to each other on the same layer and have an integral shape.

The curved portion CRL-B may overlap a region GPA between the first end CR1e of the first carry line CRL1 and the second end CR3e of the third carry line CRL3.

The curved portion CRL-B may be located between the first line portion CLp1 and the second line portion CLp2 to connect between the first line portion CLp1 and the second line portion CLp2. According to some embodiments of the present disclosure, the second carry line CRL2 may further include a connection portion CLcp. The connection portion CLcp may be electrically connected to the first line portion CLp1 and the second line portion CLp2. According to some embodiments of the present disclosure, the connection portion CLcp may overlap the curved portion CRL-B. Accordingly, the connection portion CLcp may overlap the region GPA between the first end CR1e and the second end CR3e. However, this is merely an example, and the position of the connection portion CLcp is not limited thereto.

The first carry line CRL1 and the first line portion CLp1 may be spaced apart in the second direction DR2, and the third carry line CRL3 and the second line portion CLp2 may be spaced apart in the second direction DR2. In addition, the first carry line CRL1 and the second line portion CLp2 may be spaced apart in the first direction DR1 and may face each other, and the third carry line CRL3 and the first line portion CLp1 may be spaced apart in the first direction DR1 and may face each other.

According to some embodiments of the present disclosure, the first carry line CRL1 and the third carry line CRL3 having ends overlapping the region in which the second stage SS-ST2 is located do not overlap each other in the second direction DR2. Therefore, the second carry line CRL2 may be designed to pass between the first end CR1e of the first carry line CRL1 and the second end CR3e of the third carry line CRL3. In this case, although the number of the carry lines CRL1, CRL2, and CRL3 overlapping the second stage SS-ST2 is three, the number of carry lines arranged in the second direction DR2 may be two. As the area or width occupied by the carry lines CRL1, CRL2, and CLR3 is relatively reduced, the width of the non-display region NDA (see FIG. 2) of the display panel DP (see FIG. 2) may be relatively reduced.

Referring to FIG. 13B, the display panel DP may further include a base layer 110 and a circuit layer 120. The configuration illustrated in FIG. 13B only illustrates some components of the display panel DP, and the display panel DP may further include a light emitting element layer including a light emitting layer including the light emitting element ED (see FIG. 4) and an encapsulation layer for covering the light emitting element layer.

The base layer 110 may be a member for providing a base surface on which the circuit layer 120 is located. The base layer 110 may have a multi-layered structure or single-layered structure. The base layer 110 may be a glass substrate, a metal substrate, a silicon substrate, a polymer substrate, or the like, but is not limited thereto.

The circuit layer 120 may be located on the base layer 110. The circuit layer 120 may include a first intermediate insulation layer ILG1 and a second intermediate insulation layer ILG2. The first insulation layer ILG1 and the second intermediate insulation layer ILG2 may each include one or more insulation layers, and each of the one or more insulation layers may be an inorganic insulation layer or organic insulation layer.

According to some embodiments of the present disclosure, the first line portion CLp1, the second line portion CLp2, and the curved portion CRL-B may be located on the same layer. For example, the first line portion CLp1, the second line portion CLp2, and the curved portion CRL-B may be located between the base layer 110 and the first intermediate insulation layer ILG1. The connection portion CLcp may be located on a different layer from the first line portion CLp1, the second line portion CLp2, and the curved portion CRL-B. For example, the connection portion CLcp may be located between the first intermediate insulation layer ILG1 and the second intermediate insulation layer ILG2.

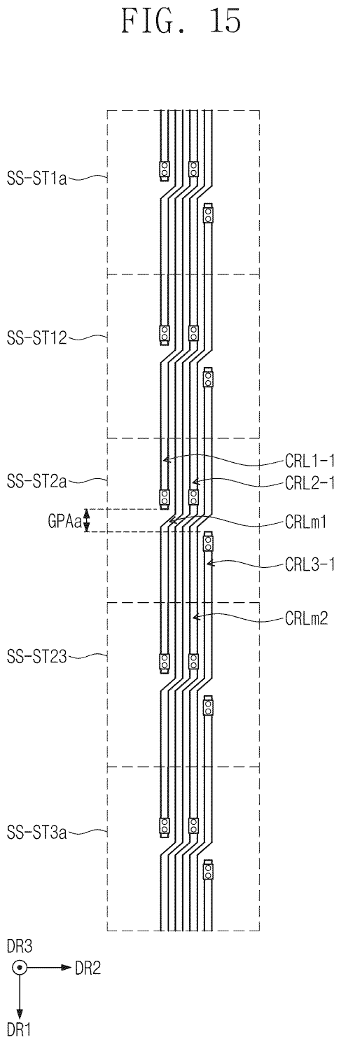

FIG. 14 is a plan view illustrating a plurality of carry lines CRL1a, CRL2a, and CRL3a according to some embodiments of the present disclosure. In describing FIG. 4B, the same reference numerals are given to the same components as the components described with reference to FIG. 13A, and descriptions thereof are omitted.

Referring to FIG. 14, three second-type stages SS-ST1, SS-ST2, and SS-ST3 arranged along the first direction DR1 and three carry lines CRL1, CRL2a, and CRL3 connected thereto are illustrated.

The second carry line CRL2a may include a first line portion CLp1a, a second line portion CLp2a electrically connected to the first line portion CLp1a, and a curved portion CRL-Ba. The curved portion CRL-Ba may overlap the region GPA between the first end CR1e of the first carry line CRL1 and the second end CR3e of the third carry line CRL3.

According to some embodiments of the present disclosure, the second carry line CRL2a may further include a connection portion CLcpa. The connection portion CLcpa may be electrically connected to the first line portion CLp1a and the second line portion CLp2a. According to some embodiments of the present disclosure, the connection portion CLcpa may overlap the first line portion CLp1a or the second line portion CLp2a. FIG. 14 illustrates an example in which the connection portion CLcpa overlaps the first line portion CLp1a.

FIG. 15 is a plan view illustrating a plurality of carry lines CRL1-1, CRL2-1, CRL3-1, CRLm1, and CRLm2 according to some embodiments of the present disclosure.

Referring to FIG. 15, five second-type stages SS-ST1a, SS-ST12, SS-ST2a, SS-ST23, and SS-ST3a arranged along the first direction DR1 and five carry lines CRL1-1, CRL2-1, CRL3-1, CRLm1, and CRLm2 connected thereto are illustrated.

The second-type stages SS-ST1a, SS-ST12, SS-ST2a, SS-ST23, and SS-ST3a are referred to as a first stage SS-ST1a, a second stage SS-ST2a, a third stage SS-ST3a in the description below with reference to FIG. 15, a first intermediate stage SS-ST12, a second intermediate stage SS-ST23, and the carry lines CRL1, CRL2-1, CRL3-1, CRLm1, and CRLm2 are referred to as a first carry line CRL1-1, a second carry line CRL2-1, a third carry line CRL3-1, a first intermediate carry line CRLm1, and a second intermediate carry line CRLm2 in the description below with reference to FIG. 15.

According to some embodiments of the present disclosure, the first stage SS-ST1a may be an X−2-th stage, the second stage SS-ST2a may be an X-th stage, and the third stage SS-ST3a may be an X+2-th stage. The first intermediate stage SS-ST12 may be an X−1-th stage, and the second intermediate stage SS-ST23 may be an X+1-th stage. X may be an integer of 2 or greater.

The first carry line CRL1-1 may be connected to the first stage SS-ST1a and the second stage SS-ST2a. The second carry line CRL2-1 may be connected to the first stage SS-ST1a, the second stage SS-ST2a, and the third stage SS-ST3a. The third carry line CRL3-1 may be connected to the second stage SS-ST2a, and the third stage SS-ST3a. The first intermediate carry line CRLm1 and the second intermediate carry line CRLm2 may be respectively connected to the first intermediate stage SS-ST12 and the second intermediate stage SS-ST23.

According to some embodiments of the present disclosure, in the second stage SS-ST2a, an end of the first carry line CRL1-1 and an end of the third carry line CRL3-1 are located. The ends may not overlap each other in the second direction DR2. In addition, when viewed in the second direction DR2, the first carry line CRL1-1 and the third carry line CRL3-1 may not overlap each other, and a region GPAa between the first carry line CRL1-1 and the third carry line CRL3-1 may be defined.

According to some embodiments of the present disclosure, the second carry line CRL2-1, the first intermediate carry line CRLm1, and the second intermediate carry line CRLm2 may be curved and extended in the region GPAa. In this case, although the number of carry lines CRL1-1, CRL2-1, CRL3-1, CRLm1, and CRLm overlapping the second stage SS-ST2a is five, the number of carry lines arranged in the second direction DR2 may be four. As the area or width occupied by the carry lines CRL1-1, CRL2-1, CRL3-1, CRLm1, and CRLm is relatively reduced, the width of the non-display region NDA (see FIG. 2) of the display panel DP (see FIG. 2) may be relatively reduced.

As described above, a display panel includes a plurality of stages, wherein the plurality of stages may be electrically connected to each other by a plurality of carry lines. Ends of some carry lines among the plurality of carry lines may overlap one stage. Within the one stage, the ends of some carry lines may be spaced apart when viewed in a set or predetermined direction, and other carry lines may be designed to pass between the ends of some carry lines. In this case, the width or area of a space occupied by the carry lines in the one stage may be relatively reduced. Accordingly, the width of a non-display region of the display panel may be relatively reduced.

Although aspects of some embodiments of the present disclosure have been described with reference to some embodiments of the present disclosure, it will be understood by those skilled in the art that various modifications and changes in form and details may be made therein without departing from the spirit and scope of embodiments according to the present disclosure as set forth in the following claims, and their equivalents. Accordingly, the technical scope of embodiments according to the present disclosure are not intended to be limited to the contents set forth in the detailed description of the specification, but is intended to be defined by the appended claims, and their equivalents.

### DESCRIPTION OF SOME OF THE REFERENCE NUMERALS OR SYMBOLS

DP: Display panel PX: Plurality of pixels

SS-ST1: First stage SS-ST2: Second stage

SS-ST3: Third stage CRL1: First carry line

CRL2: Second carry line CRL3: Third carry line

CR1e: End of first carry line CR3e: End of third carry line

CK1, CK2, CK3, CK4, CK5, CK6: First to sixth clock signals

SS1, SS2, SS3, SS4, SS5, SS6: First to sixth scan signals.

What is claimed is:

1. A display panel comprising:
a plurality of pixels;
a plurality of scan lines electrically connected to the plurality of pixels;
a plurality of stages electrically connected to the plurality of scan lines and arranged along a first direction; and
a plurality of carry lines connected to the plurality of stages,
wherein:
the plurality of stages include a first stage, a second stage, and a third stage;
the plurality of carry lines include a first carry line connected to the first stage and the second stage, a second carry line connected to the first stage, the second stage, and the third stage, and a third carry line connected to the second stage and the third stage; and
in a region in which the second stage is located, the first carry line and the third carry line do not overlap each other in a second direction intersecting the first direction.

2. The display panel of claim 1, wherein the second carry line comprises a curved portion, wherein the curved portion overlaps a region between an end of the first carry line and an end of the third carry line.

3. The display panel of claim 1, wherein the first stage is an X−1-th stage, the second stage is an X-th stage, and the third stage is an X+1-th stage, wherein the X is an integer of 2 or greater.

4. The display panel of claim 1, wherein the first stage is an X−2-th stage, the second stage is an X-th stage, and the third stage is an X+2-th stage, wherein the X is an integer of 3 or greater.

5. The display panel of claim 1, wherein the second carry line comprises a first line portion, a second line portion electrically connected to the first line portion, and a connection portion connected to the first line portion and the second line portion,
wherein:
the first line portion and the second line portion are on a same layer; and
the connection portion is on a different layer from the first line portion and the second line portion.

6. The display panel of claim 5, wherein:
the first carry line and the first line portion are spaced apart in a second direction intersecting the first direction; and
the second line portion and the third carry line are spaced apart in the second direction.

7. The display panel of claim 5, wherein the first carry line is spaced apart from the second line portion in the first direction, and the first line portion and the third carry line are spaced apart in the first direction.

8. The display panel of claim 1, wherein the second stage is electrically connected to six scan lines among the plurality of scan lines.

9. The display panel of claim 1, wherein each of the plurality of stages comprises a plurality of clock terminals configured to receive a plurality of clock signals, wherein:
in a first mode driven at a first frequency, the plurality of clock signals have different phases from each other; and
in a second mode driven at a second frequency higher than the first frequency, some clock signals among the plurality of clock signals have a same phase.

10. The display panel of claim 1, wherein the plurality of pixels comprise Y pixels (Y is an integer of 2 or greater) arranged along the first direction, wherein the second stage outputs scan signals to Y scan lines connected to the Y pixels among the plurality of scan lines.

11. The display panel of claim 10, wherein:
in a first mode driven at a first frequency, first-mode scan signals output to the Y scan lines have different phases from each other; and
in a second mode driven at a second frequency higher than the first frequency, some second-mode scan signals among second-mode scan signals output to the Y scan lines have a same phase as each other.

12. The display panel of claim 1, wherein:
the plurality of scan lines comprise a plurality of first scan lines and a plurality of second scan lines;
the plurality of stages include a plurality of first-type stages electrically connected to the plurality of first scan lines and a plurality of second-type stages electrically connected to the plurality of second scan lines; and
the plurality of first-type stages and the plurality of second-type stages are alternately and repeatedly arranged one by one along the first direction.

13. The display panel of claim 12, wherein each of the plurality of pixels comprises a light emitting element, a first transistor, a second transistor, and a third transistor, wherein the first transistor is connected to the light emitting element, the second transistor is connected to a gate electrode of the first transistor, and the third transistor is connected to the light emitting element, wherein an operation of the second transistor is controlled by one corresponding first scan line among the plurality of first scan lines, and an operation of the third transistor is controlled by one corresponding second scan line among the plurality of second scan lines.

14. A display panel comprising:
a plurality of pixels arranged along a first direction;
a plurality of scan lines connected to the plurality of pixels;
a reference stage configured to output a plurality of scan signals to the plurality of scan lines;
a first peripheral stage spaced apart from the reference stage in the first direction;
a second peripheral stage spaced apart from the first peripheral stage in the first direction with the reference stage interposed therebetween;
a first peripheral carry line configured to transfer a carry signal output from the first peripheral stage; and
a second peripheral carry line configured to transfer a carry signal output from the second peripheral stage, wherein the first peripheral carry line and the second peripheral carry line do not overlap each other in a second direction intersecting the first direction.

15. The display panel of claim 14, wherein:
in a first mode driven at a first frequency, the plurality of scan signals have different phases from each other; and
in a second mode driven at a second frequency higher than the first frequency, some scan signals among the plurality of scan signals have a same phase as each other.

16. The display panel of claim 14, further comprising a carry line configured to output a carry signal generated from the reference stage, wherein the carry line includes a curved portion, wherein the curved portion overlaps a region between an end of the first peripheral carry line and an end of the second peripheral carry line.

17. The display panel of claim 16, wherein the carry line further comprises a first line portion, a second line portion electrically connected to the first line portion, and a connection portion connected to the first line portion and the second line portion,
wherein:
the first line portion and the second line portion are on a same layer; and
the connection portion is on a different layer from the first line portion and the second line portion.

18. The display panel of claim 17, wherein:
the first peripheral carry line and the first line portion are spaced apart in the second direction intersecting the first direction; and
the second line portion and the second peripheral carry line are spaced apart in the second direction.

19. The display panel of claim 17, wherein the first peripheral carry line is spaced apart from the second line portion in the first direction, and the first line portion and the second peripheral carry line are spaced apart in the first direction.

20. An electronic device comprising:
a plurality of pixels arranged along a first direction;
a stage including a plurality of clock terminals configured to control an operation of the plurality of pixels and configured to receive a plurality of clock signals:
a first carry line configured to transfer a first carry signal to the stage;
a second carry line configured to transfer a second carry signal generated from the stage; and
a third carry line configured to transfer a third carry signal to the stage,
wherein:
when viewed in a second direction intersecting the first direction, the first carry line and the third carry line are spaced apart from each other;
in a first mode driven at a first frequency, the plurality of clock signals have different phases from each other; and
in a second mode driven at a second frequency higher than the first frequency, some clock signals among the plurality of clock signals have a same phase.
